(19) United States
(12) Patent Application Publication
(10) Pub. No.: US 2023/0271229 A1
(43) Pub. Date: Aug. 31, 2023

(54) METHOD OF CLEANING WORK AND CLEANING SYSTEM FOR WORK

(71) Applicant: SUMCO CORPORATION, Tokyo (JP)

(72) Inventors: Kaito NODA, Tokyo (JP); Katsuro WAKASUGI, Tokyo (JP); Yuki KANEKO, Tokyo (JP); Fumitoshi IWASAKI, Tokyo (JP); Yoshihiro JAGAWA, Tokyo (JP)

(73) Assignee: SUMCO CORPORATION, Tokyo (JP)

(21) Appl. No.: 18/007,270

(22) PCT Filed: Feb. 2, 2021
(86) PCT No.: PCT/JP2021/003664

§ 371 Date: Jan. 27, 2023

(30) Foreign Application Priority Data
Jul. 30, 2020 (JP) 2020-129589

(51) Int. Cl. B08B 3/04; B08B 13/00

(52) U.S. Cl. CPC B08B 3/048; B08B 13/00; B08B 2203/005; H01L 21/67057

(57) ABSTRACT

A method and a system for cleaning a work, the sum A of the areas (mm²), the sum B of the areas (mm²) and the determined supply flow rate Q (L/min) or the supply flow rate Q (L/min) and one or both of the determined sum A of the areas (mm²) and the determined sum B of the areas (mm²) satisfy the predetermined relations.

### TECHNICAL FIELD

This disclosure relates to a method of cleaning a work and a cleaning method for a work, particularly relates to cleaning of semiconductor wafers such as silicon wafers, and more particularly relates to a cleaning method and cleaning system involving single-wafer processing dip cleaning.

### BACKGROUND

Embodiments of cleaning in the production of silicon wafers include single-wafer processing dip cleaning. In dip cleaning, a wafer placed in a cleaning tank is immersed in a cleaning solution (for example, ozone water) to remove organic matter deposited on the wafer by oxidation (the surfaces of the wafer are coated with an oxide film in the case of ozone water).

Typically, a cleaning solution such as ozone water flows into a cleaning tank from its bottom portion to fill up the cleaning tank, overflows at an upper part of the cleaning tank, and flows into drainage surrounding the cleaning tank, thus flowing out of the cleaning tank. For example, in a single-wafer processing cleaning method, wafers are one by one set on an arm and transferred into a cleaning tank in which a cleaning solution flows as described above, and each wafer is subjected to cleaning of its whole surfaces.

In such cleaning methods, in order to increase the uniformity of cleaning in a wafer plane, the flow of a cleaning solution inside a cleaning tank is controlled in various ways. For example, JP H04-056321 A (PTL 1) discloses that one pipe having many holes in its lower part is horizontally placed at a bottom portion of a cleaning tank, a cleaning solution is discharged from the holes, and a plurality of flow-controlling panels having a plurality of holes are provided between wafers and the pipe. Further, for example, JP H09-232272 A (PTL 2) discloses that a balance tank having an inlet for a cleaning solution is provided in a lower portion of a cleaning tank, and a plurality of perforated baffles provided with a plurality of communication holes through which the cleaning solution flows. Further, PTL 2 discloses that the perforated baffles are formed such that the ones provided at upper positions have the communication holes with smaller diameters.

### CITATION LIST

### Patent Literature

PTL 1: JP H04-056321 A

PTL 2: JP H09-232272 A

### SUMMARY

### Technical Problem

Now, in cleaning of wafers, the amount of a cleaning solution consumed for a wafer is desirably reduced, so that the cleaning tank is preferably as small as possible. In single-wafer processing cleaning in particular, the throughput is lower than that of batch cleaning, so that many cleaning tanks are necessarily provided, and it is particularly desired that each cleaning tank is as small as possible. Further, when the cleaning tanks are large, the flow of the cleaning solution is hardly controlled and particles are hardly discharged from the tanks, thus the cleaning tanks are desirably smaller.

However, in the technique of PTL 1, since the pipe is horizontally placed and jets of the cleaning solution are emitted from the holes in the lower part toward the bottom of the cleaning tank to reduce the flow speed of the solution, which requires a space for providing the pipe and increases the size of the cleaning tank. Further, in PTL 2, if the flow of the cleaning solution reaches the perforated baffle without having been sufficiently moderated, the cleaning solution mostly flows through part of the holes, which would make it impossible to obtain sufficient flow controlling effects, requires to provide a large buffer tank to address this, and thus requires a larger cleaning tank. Moreover, the problems as described above may be found not only in cases where wafers are to be cleaned, but also in cases where general works to be subjected to similar cleaning.

It could therefore be helpful to provide a method of cleaning a work and a cleaning system for a work that make it possible to control the flow of a cleaning solution inside a cleaning tank without increasing the size of the cleaning tank beyond necessity.

### Solution to Problem

This disclosure primarily includes the following features.
(1) A method of cleaning a work, comprising:
a step of preparing a cleaning tank;
a step of setting a work in the cleaning tank; and
a step of supplying a cleaning solution into the cleaning tank through a cleaning solution supply port provided in a bottom portion of the cleaning tank, thereby cleaning the work,
wherein two baffles including an upper baffle and a lower baffle situated closer to the bottom portion of the cleaning tank than the upper baffle are placed between a position where the work is set and the bottom portion,
the upper baffle and the lower baffle each have a plurality of holes, a diameter of the holes of the upper baffle is smaller than a diameter of the holes of the lower baffle,
the method further comprises a step of determining a supply flow rate Q (L/min) of the cleaning solution based on a sum A of areas of the plurality of holes of the lower baffle (mm²) and a sum B of areas of the plurality of holes of the upper baffle (mm²),
the step of supplying the cleaning solution to clean the work further comprises one of supplying the cleaning solution at the determined supply flow rate Q (L/min) and determining the sum A of the areas (mm²) and/or the sum B or the areas (mm²) based on the supply flow rate Q (L/min),
in the step of preparing the cleaning tank, the cleaning tank provided with one or both of the lower baffle having the plurality of holes having the determined sum A of the areas (mm²) and the lower baffle having the plurality of holes having the determined sum B of the areas (mm²) is prepared, and
either the sum A of the areas (mm²), the sum B of the areas (mm²) and the determined supply flow rate Q (L/min) or the supply flow rate Q (L/min) and one or both of the determined sum A of the areas (mm²) and the determined sum B of the areas (mm²) satisfy relations (a):

B/A≥5.6×10⁻² exp(0.46Q), and

B/A≤−6.9×10⁻²Q²+1.2Q+3.4.
(2) The method of cleaning a work, according to (1) above,
wherein either the sum of the areas A (mm²), the sum of the areas B (mm²), and the determined supply flow rate Q (L/min) or the supply flow rate Q (L/min) and one or both of the determined sum of the areas A (mm²) and the determined sum of the areas B (mm²) further satisfy relations (b):

B/A≥3.2×10⁻²Q²+0.36Q−0.47, and

B/A≤−5.1×10⁻²Q²+1.1Q+0.62.
(3) The method of cleaning a work, according to (1) or (2) above,
wherein a distance between the two baffles is 10 mm or more.
(4) The method of cleaning a work, according to any one of (1) to (3) above,
wherein the work is a wafer, and
an area of a horizontal cross section of the cleaning tank at a height of a center of the wafer is 9000 mm² or more and 60000 mm² or less with the wafer being set in the cleaning tank.
(5) A cleaning system for a work, comprising a cleaning tank,
wherein the cleaning tank is configured such that a work can be set in the cleaning tank,
a cleaning solution supply port supplying a cleaning solution into the cleaning tank is provided in a bottom portion of the cleaning tank,
wherein two baffles including an upper baffle and a lower baffle situated closer to the bottom portion of the cleaning tank than the upper baffle are placed between a position where the work is set in the cleaning tank and the bottom portion of the cleaning tank,
the upper baffle and the lower baffle each have a plurality of holes,
a diameter of the holes of the upper baffle is smaller than a diameter of the holes of the lower baffle,
the system further comprises a calculation unit determining a supply flow rate Q (L/min) of the cleaning solution based on a sum A of areas of the plurality of holes of the lower baffle (mm²) and a sum B of areas of the plurality of holes of the upper baffle (mm²), and a control unit performing control to supply the cleaning solution at the determined supply flow rate Q (L/min), and
the sum A of the areas (mm²), the sum B of the areas (mm²), and the supply flow rate Q (L/min) determined by the calculation unit satisfy relations (a):

B/A≥5.6×10⁻² exp(0.46Q), and

B/A≤−6.9×10⁻²Q²+1.2Q+3.4.
(6) The cleaning system for a work, according to (5) above,
wherein the sum A of the areas (mm²), the sum B of the areas (mm²), and the supply flow rate Q (L/min) determined by the calculation unit satisfy relations (b):

B/A≥3.2×10⁻²Q²+0.36Q−0.47, and

B/A≤−5.1×10⁻²Q²+1.1Q+0.62.
(7) The cleaning system for a work, according to (5) or (6) above,
wherein a distance between the two baffles is 10 mm or more.
(8) The cleaning system for a work, according to any one of (5) to (7) above,
wherein the work is a wafer, and
an area of a horizontal cross section of the cleaning tank at a height of a center of the wafer is 9000 mm² or more and 60000 mm² or less with the wafer being set in the cleaning tank.

### Advantageous Effect

This disclosure can provide a method of cleaning a work and a cleaning system for a work that make it possible to control the flow of a cleaning solution inside a cleaning tank without increasing the size of the cleaning tank beyond necessity.

### BRIEF DESCRIPTION OF THE DRAWINGS

In the accompanying drawings:

FIG. 1 is a schematic view of a cleaning system for a work, according to an embodiment of this disclosure;

FIG. 2 is a flowchart of a method of cleaning a work, according to an embodiment of this disclosure;

FIG. 3 is a diagram illustrating the relationship of the flow rate of the cleaning solution and B/A with the effect; and

FIG. 4 is a diagram illustrating the relationship between the distance between baffles and the time required to discharge particles.

### DETAILED DESCRIPTION

Embodiments of a method and a system for cleaning a wafer, according to this disclosure will now be described in detail with reference to the drawings.

<Cleaning System for Work>

First, a cleaning system for a work, according to one embodiment of this disclosure is described. An embodiment of a method of cleaning a wafer, to be described may be performed, for example, using this cleaning system for a work.

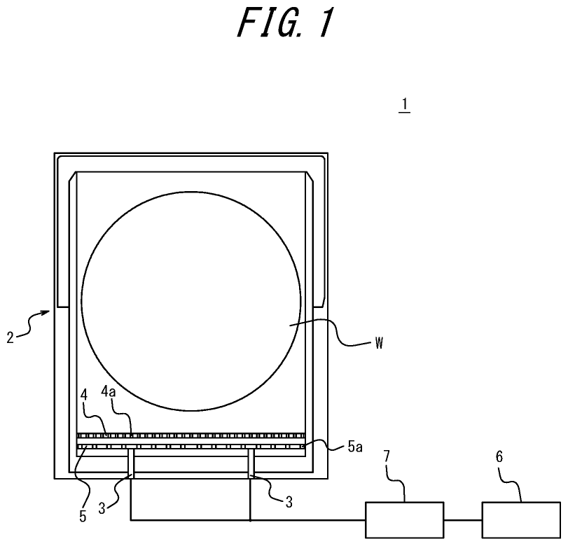

FIG. 1 is a schematic view of a cleaning system for a work, according to an embodiment of this disclosure. As illustrated in FIG. 1, a cleaning system for a work 1, according to this embodiment includes a cleaning tank 2, a calculation unit 6, and a control unit 7.

The cleaning tank 2 is configured such that a work W can be set in the cleaning tank 2. The work W is an object to be subjected to cleaning, and may be, for example, a semiconductor wafer such as a silicon wafer. In this example, the work W is a silicon wafer. The illustrated cleaning tank 2 is a single-wafer processing cleaning tank configured such that one wafer can be set, and the cleaning tank can be suitably applied to dip cleaning. The diameter of the work W may be, for example, but not limited to, 200 mm, 300 mm, or 450 mm when the work W is a wafer. The cleaning tank 2 is preferably fairly small within a range depending on the size of the work W (allowing the work W having a predetermined size to be set therein). Specifically, when the work W is a wafer, with the wafer being set in the cleaning tank 2, the area of a horizontal cross section of the cleaning tank 2 at the height of the center of the wafer is preferably 9000 mm² or more and 60000 mm² or less. When the horizontal sectional area is 9000 mm² or more, for example, a wafer having a diameter of 450 mm can be set, and when the horizontal sectional area is 60000 mm² or less, the amount of the cleaning solution to be consumed can be small. The material of the cleaning tank 2 may be, but is not limited to, quartz glass. The work W is supported by a holder (not shown) such that the plane of the work W is perpendicular to the horizontal direction. The work W is transferred into and set in the cleaning tank 2 for example using an arm (not shown). The arm may also be used to unload the work W having been cleaned from the cleaning tank.

As illustrated in FIG. 1, cleaning solution supply ports (nozzles) 3 (two in this example) supplying the cleaning solution into the cleaning tank 2 are provided in a bottom portion of the cleaning tank 2. The number of the cleaning solution supply ports 3 is not limited and may also be one or three or more. To make uniform the flow of the cleaning solution in the cleaning tank 2, the cleaning solution supply ports 3 are preferably placed in symmetric positions about the work W. For example, as illustrated in the diagram, the cleaning solution supply ports may be placed at equal distances from a position immediately under the center of the wafer when viewed from the front of the wafer plane.

Further, as illustrated in FIG. 1, two baffles including an upper baffle 4 and a lower baffle 5 situated closer to the bottom portion of the cleaning tank 2 than the upper baffle 4 are placed between a position where the work W is set in the cleaning tank 2 and the bottom of the cleaning tank 2. As illustrated in the diagram, the two baffles are each placed such that the upper and lower surfaces are horizontal. The upper baffle 4 and the lower baffle 5 have a plurality of holes 4a and 5a through which the cleaning solution can flow, respectively. The holes are arranged in a lattice pattern, in which the holes are arranged at regular intervals (for example, with a pitch of 5 mm to 20 mm, but not limited thereto) in one column, and a plurality of such columns are arranged (in the row direction). For example, the holes can be arranged such that the holes coincide when the odd-numbered columns are imaginarily moved in the row direction to be superimposed on the even numbered columns in the row direction; alternatively, the holes can be arranged in a rhombic lattice pattern such that the holes are deviated from the lattice points by a half pitch in the column direction when the odd-numbered columns are imaginarily superimposed on the even numbered columns in the row direction. The plurality of holes provided in the upper baffle 4 are preferably uniform in size; meanwhile, the plurality of holes provided in the lower baffle 5 are preferably uniform in size. In this embodiment, the diameter of the holes in the upper baffle 4 is smaller than the diameter of the holes in the lower baffle 5. Note that in the case where the diameters of the holes provided in the upper baffle 4 are not uniform and/or the diameters of the holes provided in the lower baffle 5 are not uniform, when the average of the diameters of the holes in each baffle is determined, the average diameter of the holes in the upper baffle 4 is smaller than the average diameter of the holes in the lower baffle 5. The diameter of the holes in the lower baffle 5 may be, but is not limited to, 2 mm to 7 mm, and the diameter of the upper baffle 4 may be, but is not limited to, 1 mm to 5 mm while being smaller than the diameter of the holes in the lower baffle 5. The distance (the shortest distance) between the two baffles 4 and 5 is preferably 10 mm or more. A longer distance between the two baffles 4 and 5 ensures a larger region serving as a buffer that reduces the flow rate of the cleaning solution having passed through the lower baffle 5, which can make the flow more uniform, thus the above distance is preferably 10 mm or more. On the other hand, in terms of avoiding the necessity for a large-sized cleaning tank 2 and considering that the effect of the buffer is saturated as the distance is increased, the above distance is preferably 40 mm or less.

In this example, ozone water is used as the above cleaning solution, which makes it possible to remove particles and also form an oxide film on the surfaces of the wafer. Other examples of the cleaning solution include a solution containing a given cleaning agent component and pure water.

Now, when the cleaning solution is supplied into the cleaning tank 2 from the cleaning solution supply ports 3 using for example a pump, the cleaning solution passes through the plurality of holes 5a of the lower baffle 5, then passes through the plurality of holes 4a of the upper baffle 4, and flows to an upper part of the cleaning tank 2, and is recovered in an overflow tank provided on the upper part. After being subjected to processes such as filtering, the recovered cleaning solution is supplied again into the cleaning tank 2 from the cleaning solution supply ports 3 using for example a pump.

The calculation unit 6 determines the supply flow rate Q (L/min) of the cleaning solution based on the sum A of the areas of the plurality of holes 5a in the lower baffle 5 (mm²) and the sum B of the areas of the plurality of holes 4a in the upper baffle 4 (mm²). The calculation unit 6 may be a given known calculator. In this embodiment, the calculation unit 6 determines the supply flow rate Q (L/min) of the cleaning solution based on B/A. More specifically, the supply flow rate Q (L/min) of the cleaning solution is determined based on the relations (a) (preferably also on the relations (b)) to satisfy the relations. In this example, the way of determining the supply flow rate is not limited as long as the relations (a) (preferably also the relations (b)) are satisfied. For example, the supply flow rate may be set to the minimum value in that range or a value close to the minimum value to minimize the amount of the cleaning solution to be used; the supply flow rate may be set to the maximum value in that range or a value close to the maximum value to reduce the cleaning time; or the supply flow rate may be set to correspond to the barycentric point or its vicinity in a region where the horizontal axis represents B/A and the vertical axis represents Q such that the relations (a) (preferably also the relations (b)) are more reliably satisfied even when for example the supply flow rate varies.

The control unit 7 performs control to supply the cleaning solution at the determined supply flow rate Q (L/min). Specifically, by way of example, the supply flow rate can be controlled to achieve the determined supply flow rate Q by performing control to adjust the size of the flow path by opening/closing a valve of the cleaning solution supply ports 3. The control unit 7 may include a given known processor.

As is also described in Examples below, the above sum A of the areas of the plurality of holes 5a in the lower baffle 5 (mm²) and the above sum B of the areas of the plurality of holes 4a in the upper baffle 4 (mm²), and the above supply flow rate Q (L/min) determined by the calculation unit 6 satisfy the relations (a):

B/A≥5.6×10⁻² exp(0.46Q), and

B/A≤−6.9×10⁻²Q²+1.2Q+3.4.

Preferably, the above sum A of the areas of the plurality of holes 5a in the lower baffle 5 (mm²) and the above sum B of the areas of the plurality of holes 4a in the upper baffle 4 (mm²), and the above supply flow rate Q (L/min) determined by the calculation unit 6 also satisfy the relations (b):

B/A≥3.2×10⁻²Q²+0.36Q−0.47, and

B/A≤−5.1×10⁻²Q²+1.1Q+0.62.

The operation and effect of the cleaning system for a work, according to this embodiment will now be described.

First, in the cleaning system for a work, according to this embodiment, the diameter of the holes 4a in the upper baffle 4 is smaller than the diameter of the holes 5a in the lower baffle 5. Thus, the flows of the cleaning solution having passed through the holes 5a of the lower baffle 5 cannot all pass through the holes 4a of the upper baffle 4 exactly above the holes 5a and run also toward the other holes 4a along the upper baffle 4. This can reduce the nonuniformity of the flows among the holes. It should be noted that when the diameter of the holes 4a of the upper baffle 4 is equal to or larger than the holes 5a of the lower baffle 5, even if the above relations (a) are satisfied (or even if (a) and (b) are satisfied), sufficient flow controlling effects cannot be obtained.

Now, as described below, the present inventors ascertained that the relative relationship between the sum A of the areas and the sum B of the areas has an influence on the flow controlling effects, and these effects also depend on the supply flow rate Q.

Specifically, when the sum B of the areas is extremely larger than the sum A of the areas (for example, B/A is too large), the pressure of the flows through the holes 5a of the lower baffle 5 is too high (relatively with respect to that on the upper baffle), which increases the nonuniformity of the flows of the cleaning solution reaching the upper baffle 4; moreover, no pressure difference is produced at the upper baffle 4, leading to smaller flow controlling effects. On the other hand, when the sum B of the areas is extremely smaller than the sum A of the areas (for example, B/A is too small), the control of the flows through the lower baffle 5 is insufficient and the pressure applied to the holes in the upper baffle 4 is too high, so that the flows of the cleaning solution that have passed thought the upper baffle 5 becomes nonuniform, thus the flow controlling effects would be smaller.

Further, as the supply flow rate Q is higher, the relative relationship between the sum A of the areas and the sum B of the areas that is suitable for obtaining the flow controlling effects varies (for example, in the case of B/A, its value increases). This is because the nonuniformity of the flow rate of the flows passing through the baffles is high when the supply flow rate Q is high. In order to reduce the nonuniformity, it is necessary to reduce the sum A of the areas of the holes 5a of the lower baffle 5 to prevent the flows from easily passing through the holes 5a of the lower baffle 5, and to reduce the force of the cleaning solution issued from the cleaning solution supply ports 3 before the solution passes through the lower baffle 5. Further, when the supply flow rate Q is high, the pressure applied to the upper baffle 4 is too high, so that the flow rate of the cleaning solution that passes through the holes 4a of the upper baffle 4 is too high, which increases the nonuniformity of the cleaning solution having passed through the holes 4a. Consequently, it is necessary to reduce the nonuniformity of the flow rate of the cleaning solution by relatively increasing the sum B of the areas of the holes in the upper baffle 4 to reduce the pressure applied to the upper baffle 4.

Based on the above and also on the facts to be also described in Examples below, the present inventors found that the desired effect can effectively be obtained by satisfying the above relations (a) (preferably the above relations (b) as well). Specifically, the rate of the cleaning solution supplied from the cleaning solution supply ports 3 can be reduced by the lower baffle 5 and the nonuniformity of the flows of the cleaning solution can be reduced before the flows reach the upper baffle 4. After that, a pressure difference is produced around the upper baffle 4, which allows the cleaning solution to uniformly pass through any hole 4a of the upper baffle 4, thus the cleaning solution can uniformly flow upward after passing through the upper baffle 4. This uniform upward flow makes it possible to quickly discharge particles flowing in the cleaning tank 2.

Consequently, the supply flow rate Q (L/min) of the cleaning solution is determined based on the sum A of the areas (mm²) and the sum B of the areas (mm²) using the calculation unit 6; control is performed by the control unit 7 to supply the cleaning solution at the supply flow rate Q (L/min) determined by the calculation unit 6; and the sum A of the areas (mm²) and the sum B of the areas (mm²), and the determined supply flow rate Q (L/min) satisfy the relations (a), thus the flows of the cleaning solution can be effectively controlled.

As described above, a cleaning system for a work, according to this embodiment can control the flow of a cleaning solution inside a cleaning tank without increasing the size of the cleaning tank beyond necessity.

Now, for a cleaning system for a work, according to this disclosure, the sum A of the areas (mm²) and the sum B of the areas (mm²), and the determined supply flow rate Q (L/min) preferably satisfy the relations (b) as well. As will also be described in Examples below, this can control the flow of the cleaning solution in the cleaning tank more uniformly.

Further, for the cleaning system for a work, according to this disclosure, the distance between the two baffles 4 and 5 is preferably 10 mm or more. This ensures a larger region serving as a buffer that reduces the flow rate of the cleaning solution having passed through the lower baffle 5, which can make the flow more uniform. Further, the distance (the shortest distance) between the bottom of the cleaning tank 2 and the lower baffle 5 is also preferably 10 mm or more. This ensures a larger region serving as a buffer that reduces the flow rate of the cleaning solution while the cleaning solution is supplied from the cleaning solution supply ports 3 and reaches the lower baffle 5, which can make the flow more uniform.

Moreover, for the cleaning system for a work, according to this disclosure, the work is a wafer, and with the wafer being set in the cleaning tank 2, the area of a horizontal cross section of the cleaning tank 2 at the height of the center of the wafer is preferably 9000 mm² or more and 60000 mm² or less. When the horizontal sectional area is 9000 mm² or more, for example, a wafer having a diameter of 450 mm can be contained, and when the horizontal sectional area is 60000 mm² or less, the amount of the cleaning solution to be consumed can be small. Further, for a cleaning tank 2 with a size in this range, when the diameter of the holes 4a in the upper baffle 4 is made smaller than the holes 5a of the lower baffle 5, and the above relations (a) are satisfied (preferably, the relations (b) as well), larger flow controlling effects can be obtained.

<Method of Cleaning Work>

Next, a method of cleaning a work, according to one embodiment of this disclosure will be described.

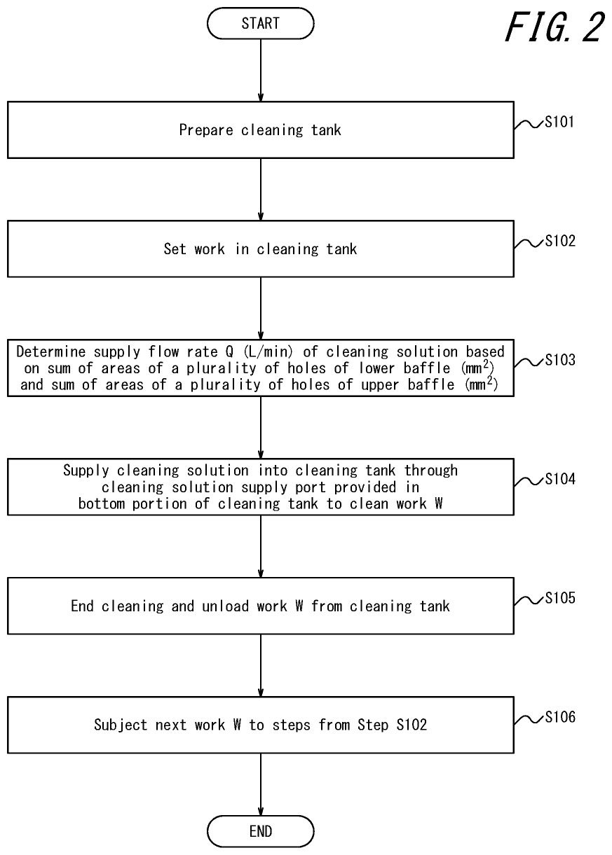

FIG. 2 is a flowchart of a method of cleaning a work, according to an embodiment of this disclosure. As illustrated in FIG. 2, in this embodiment, first, the cleaning tank 2 is prepared (Step S101). The cleaning tank 2 and the components included in the cleaning tank 2 are as described with respect to the cleaning system for a work, described above, thus the description will not be repeated.

Next, a work W is set in the cleaning tank 2 (Step S102). The setting of the work W inside the cleaning tank may be done for example by supporting the work W such that the plane of the work W is perpendicular to the horizontal direction using a holder (not shown) as described above, and transferring the work W into the cleaning tank 2 and setting the work W for example using an arm (not shown).

Next, the supply flow rate Q (L/min) of the cleaning solution is determined based on the sum A of the areas of the plurality of holes 5a in the lower baffle 5 (mm²) and the sum B of the areas of the plurality of holes 4a in the upper baffle 4 (mm²) (Step S103). This determination can be done using for example the above calculation unit 6 as described above. Note that Step S103 may be performed prior to Step S101 or Step S102.

Subsequently, the cleaning solution is supplied into the cleaning tank 2 from the cleaning solution supply ports 3 provided in a bottom portion of the cleaning tank 2 to clean the work W (Step S104). The cleaning solution to be used is as described above. Here, the supply of the cleaning solution is performed at the supply flow rate Q (L/min) determined in Step S103.

Next, the cleaning is finished and the work W is unloaded from the cleaning tank (Step S105). The unloading can be performed using for example the arm mentioned above. The next work W is subjected to the steps from Step S102 (Step S106), thus works W are cleaned one by one.

The operation and effect of the method of cleaning a work, according to this embodiment will now be described.

Also in the method of cleaning a work, according to this embodiment, since the diameter of the holes 4a of the upper baffle 4 is smaller than the diameter of the holes 5a of the lower baffle 5, the nonuniformity of the flows among the holes in the upper baffle 4 can be reduced as in the description of the system.

Further, in Step S103, the supply flow rate Q (L/min) of the cleaning solution is determined based on the sum A of the areas (mm²) and the sum B of the areas (mm²); in Step S104, the work W is cleaned by supplying the cleaning solution at the supply flow rate Q (L/min) determined in Step S103; and the sum A of the areas (mm²) and the sum B of the areas (mm²), and the determined supply flow rate Q (L/min) satisfy the relations (a), thus the flow of the cleaning solution can be effectively controlled as in the description of the system.

As described above, a method of cleaning a work, according to this embodiment can control the flow of a cleaning solution inside a cleaning tank without increasing the size of the cleaning tank beyond necessity.

In the method of cleaning a work, according to this disclosure, either the sum A of the areas (mm²) and the sum B of the areas (mm²), and the determined supply flow rate Q (L/min) or the supply flow rate Q (L/min) and the determined sum A (mm²) of areas and/or the determined sum B of the areas (mm²) preferably also satisfy the relations (b):

B/A≥3.2×10⁻²Q²+0.36Q−0.47, and

B/A≤−5.1×10⁻²Q²+1.1Q+0.62.

As will also be described in Examples below, this can control the flow of the cleaning solution in the cleaning tank more uniformly. Note that the variation of determining the sum A of the areas and/or the sum B of the areas based on the supply flow rate is described below.

In the method of cleaning a work, according to this disclosure, the distance between the two baffles is preferably 10 mm or more. This ensures a larger region serving as a buffer that reduces the flow rate of the cleaning solution having passed through the lower baffle 5, which can make the flow more uniform. Further, the distance (the shortest distance) between the bottom of the cleaning tank 2 and the lower baffle 5 is also preferably 10 mm or more. This ensures a larger region serving as a buffer that reduces the flow rate of the cleaning solution while the cleaning solution is supplied from the cleaning solution supply ports 3 and reaches the lower baffle 5, which can make the flow more uniform.

In the method of cleaning a work, according to this disclosure, the work is a wafer, and with the wafer being set in the cleaning tank, the area of a horizontal cross section of the cleaning tank at the height of the center of the wafer is preferably 9000 mm² or more and 60000 mm² or less. When the horizontal sectional area is 9000 mm² or more, for example, a wafer having a diameter of 450 mm can be contained, and when the horizontal sectional area is 60000 mm² or less, the amount of the cleaning solution to be consumed can be small. Further, for a cleaning tank 2 with a size in this range, when the diameter of the holes 4a in the upper baffle 4 is made smaller than the holes 5a of the lower baffle 5, and the above relations (a) are satisfied (preferably, the relations (b) as well), larger flow controlling effects can be obtained.

Embodiments of this disclosure have been described above; however, this disclosure is in no way limited to the above embodiments. For example, in the above example, a case of determining the supply flow rate Q based on the relationship between the sum A of the areas and the sum B of the areas is described; alternatively, the sum A of the areas and the sum B of the areas may be determined based on the supply flow rate Q. By way of example, A and/or B can be determined by determining the value of B/A such that the above relations (a) (preferably also the relations (b)) are satisfied. In an invention of the method, a cleaning tank including a lower baffle having a plurality of holes having the thus determined sum A of areas and/or an upper baffle having a plurality of holes having the thus determined sum B of areas (mm²) may be prepared; this is specifically achieved by replacing baffles with ones having holes with suitable diameters, changing and adjusting the diameter of the holes of the baffles for example by sliding, or the like. In an invention of the system,
the foregoing system may further include an arm for performing the replacement described above, or a slide adjustment mechanism for adjusting the diameter of the holes.

Further, although the above embodiment for a method of cleaning a work describes an example of cleaning using the above cleaning system for a work, but is not limited to this, and for example, the determination of the supply flow rate Q performed in Step S103 may be performed using a computer different from the system and the control of the determined supply flow rate performed in Step S104 may be performed by for example hand-operated input.

Note that for the determination of the supply flow rate Q based on the sum A of the areas and the sum B of the areas (mm²), a case of determining the supply flow rate based on B/A (specifically, based on the relations (a) (and the relations (b)) is described in the above embodiment, but the way of the determination is not limited to this. Accordingly, as also described in Examples below, the relations (a) and the relations (b) indicate borderlines between effective ranges and noneffective ranges, and the specific form of the formulae is merely for the sake of convenience and various alternatives are possible. For example, B/(A+1), B/A², or the like may be used instead of B/A, and if a domain of definition is given, the formula of Q may be represented by for example only linear equations. It should be noted that even when such alternative formulae are used, the supply flow rate Q is determined based on the sum A of the areas and the sum B of the areas (mm²). Note, however, that A, B, and Q determined (the results obtained) should satisfy the above relations (a) (and preferably the relations (b)). Also in the case of determining the sum A of the areas and/or the sum B of the areas based on the supply flow rate Q, various formulae can be used similarly.

Examples of this disclosure will now be described; however, the disclosure is no way limited to the Examples.

### EXAMPLES

### Example 1

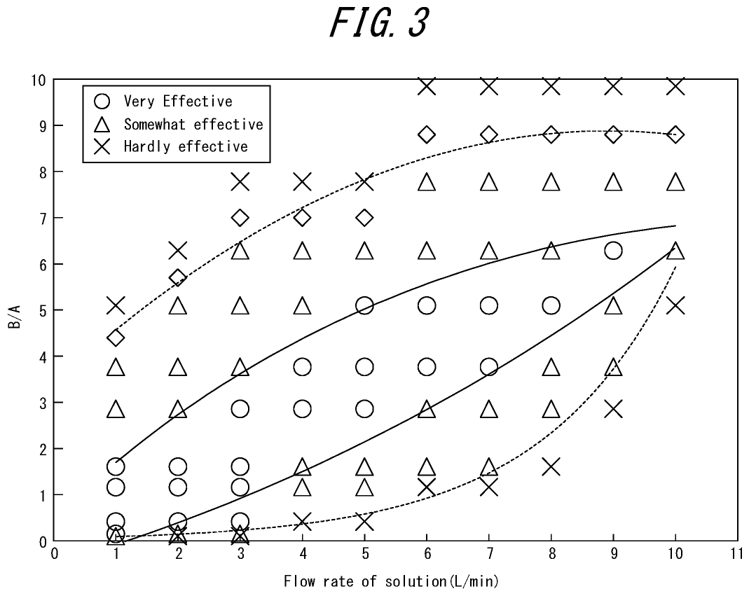

Two baffles were provided in a cleaning tank (a cleaning tank as illustrated in FIG. 1), and changes in the quantity of particles in the liquid in the cleaning tank while pure water was continuously supplied were measured using a particle counter, and the time required for the quantity of particles to become 1/10 of the quantity at the start of the supply. When the time was less than 5 min, the result was determined to be “very effective”; when the time was 5 min or more and less than 20 min, “somewhat effective”; and when the time was 20 min or more, “hardly effective” (FIG. 3).

The flow rate of pure water supplied were at 1 L/min intervals from 1 L/min to 10 L/min. The diameters of the holes in the two baffles were integers in a range of 1 mm to 5 mm such that the diameter of the holes in the upper baffle was consistently smaller than the diameter of the holes in the lower baffle. The sums A and B of the areas in the baffles were changed by changing the diameters and the numbers of the holes. The holes were made to be evenly distributed in each baffle. The openings of the solution supply nozzles were horizontally made such that a cleaning solution would not be issued directly toward the lower baffle. The two baffles were provided at 20 mm apart from each other. The cleaning tank used had a cuboidal shape with a horizontal sectional area of approximately 25000 mm² inside the tank.

In FIG. 3, the borderlines between a region corresponding to “very effective” or “somewhat effective” and regions corresponding to “hardly effective” are indicated by the broken lines, and these two borderlines correspond to the relations (a) (when the equal sign applies in the relations (a)). The borderlines were calculated by fitting. Further, the borderlines between the region corresponding to “very effective” and the regions corresponding to “somewhat effective” are indicated by the solid lines, and the two borderlines correspond to the relations (b) (when the equal sign applies in the relations (b)). Thus, the regions satisfying the relations (a) were “very effective” or “somewhat effective” and the flow controlling effects were obtained; further,
the region satisfying the relations (b) was “very effective” and larger flow controlling effects were obtained.

### Example 2

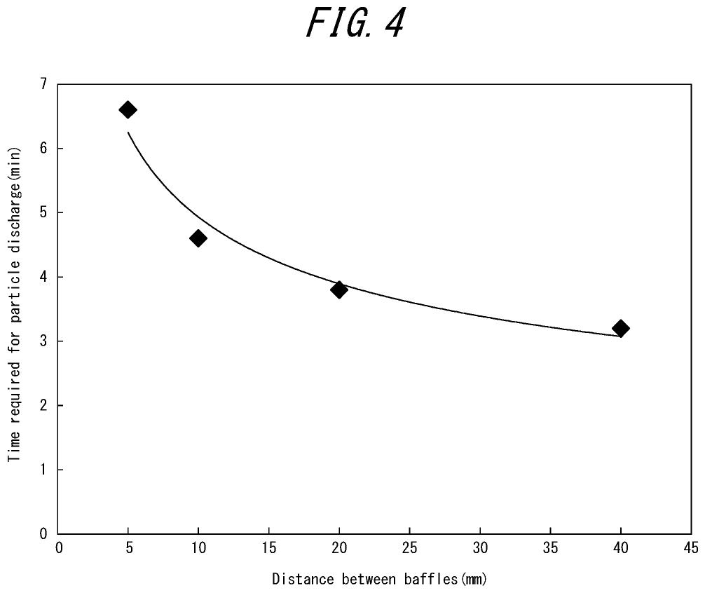

Further, a cleaning tank similar to that in Example 1 was used, and when the cleaning solution was continuously supplied while the distance between the two baffles was changed, the time required for the quantity of particles in a unit volume of the cleaning solution to become 1/10 of the quantity at the start of the cleaning solution supply was measured (FIG. 4). Now, the solution flow rate was all 5 L/min and B/A=3.8.

As illustrated in FIG. 4, it was found that when the distance between the baffles was less than 10 mm, it required 5 min or more to reduce the quantity of particles to 1/10, and the time increased sharply as the distance between the baffles was reduced.

### REFERENCE SIGNS LIST

1: Cleaning system;
2: Cleaning tank;
3: Cleaning solution supply port;
4: Upper baffle;
5: Lower baffle;
6: Calculation unit;
7: Control unit.

1. A method of cleaning a work, comprising:
a step of preparing a cleaning tank;
a step of setting a work in the cleaning tank; and
a step of supplying a cleaning solution into the cleaning tank through a cleaning solution supply port provided in a bottom portion of the cleaning tank, thereby cleaning the work,
wherein two baffles including an upper baffle and a lower baffle situated closer to the bottom portion of the cleaning tank than the upper baffle are placed between a position where the work is set and the bottom portion,
the upper baffle and the lower baffle each have a plurality of holes,
a diameter of the holes of the upper baffle is smaller than a diameter of the holes of the lower baffle,
the method further comprises a step of determining a supply flow rate Q (L/min) of the cleaning solution based on a sum A of areas of the plurality of holes of the lower baffle (mm²) and a sum B of areas of the plurality of holes of the upper baffle (mm²),
the step of supplying the cleaning solution to clean the work further comprises one of supplying the cleaning solution at the determined supply flow rate Q (L/min) and determining the sum A of the areas (mm²) and/or the sum B or the areas (mm²) based on the supply flow rate Q (L/min),
in the step of preparing the cleaning tank, the cleaning tank provided with one or both of the lower baffle having the plurality of holes having the determined sum A of the areas (mm²) and the lower baffle having the plurality of holes having the determined sum B of the areas (mm²) is prepared, and
either the sum A of the areas (mm²), the sum B of the areas (mm²) and the determined supply flow rate Q (L/min) or the supply flow rate Q (L/min) and one or both of the determined sum A of the areas (mm²) and the determined sum B of the areas (mm²) satisfy relations (a):
B/A≥5.6×10⁻² exp(0.46Q), and
B/A≤−6.9×10⁻²Q²+1.2Q+3.4.

2. The method of cleaning a work, according to claim 1,
wherein either the sum of the areas A (mm²), the sum of the areas B (mm²), and the determined supply flow rate Q (L/min) or the supply flow rate Q (L/min) and one or both of the determined sum of the areas A (mm²) and the determined sum of the areas B (mm²) further satisfy relations (b):
B/A≥3.2×10′Q²+0.36Q−0.47, and
B/A≤−5.1×10⁻²Q²+1.1Q+0.62.

3. The method of cleaning a work, according to claim 1,
wherein a distance between the two baffles is 10 mm or more.

4. The method of cleaning a work, according to claim 1,
wherein the work is a wafer, and
an area of a horizontal cross section of the cleaning tank at a height of a center of the wafer is 9000 mm² or more and 60000 mm² or less with the wafer being set in the cleaning tank.

5. A cleaning system for a work, comprising a cleaning tank,
wherein the cleaning tank is configured such that a work can be set in the cleaning tank,
a cleaning solution supply port supplying a cleaning solution into the cleaning tank is provided in a bottom portion of the cleaning tank,
wherein two baffles including an upper baffle and a lower baffle situated closer to the bottom portion of the cleaning tank than the upper baffle are placed between a position where the work is set in the cleaning tank and the bottom portion of the cleaning tank,
the upper baffle and the lower baffle each have a plurality of holes,
a diameter of the holes of the upper baffle is smaller than a diameter of the holes of the lower baffle,
the system further comprises a calculation unit determining a supply flow rate Q (L/min) of the cleaning solution based on a sum A of areas of the plurality of holes of the lower baffle (mm²) and a sum B of areas of the plurality of holes of the upper baffle (mm²), and a control unit performing control to supply the cleaning solution at the determined supply flow rate Q (L/min), and
the sum A of the areas (mm²), the sum B of the areas (mm²), and the supply flow rate Q (L/min) determined by the calculation unit satisfy relations (a):
B/A≥5.6×10⁻² exp(0.46Q), and
B/A≤−6.9×10⁻²Q²+1.2Q+3.4.

6. The cleaning system for a work, according to claim 5,
wherein the sum A of the areas (mm²), the sum B of the areas (mm²), and the determined supply flow rate Q (L/min) satisfy relations (b):
B/A≥3.2×10⁻²Q²+0.36Q−0.47, and
B/A≤−5.1×10⁻²Q²+1.1Q+0.62.

7. The cleaning system for a work, according to claim 5,
wherein a distance between the two baffles is 10 mm or more.

8. The cleaning system for a work, according to claim 5,
wherein the work is a wafer, and
an area of a horizontal cross section of the cleaning tank at a height of a center of the wafer is 9000 mm² or more and 60000 mm² or less with the wafer being set in the cleaning tank.
